(19) United States
(12) Patent Application Publication
(10) Pub. No.: US 2006/0061383 A1
(43) Pub. Date: Mar. 23, 2006

(54) On-chip power regulator for ultra low leakage current

(76) Inventors: Yihe Huang, Palo Alto, CA (US); Yuwen Wang, Fremont, CA (US); Ge Song, Santa Clara, CA (US); Chengyun Gao, San Jose, CA (US)

Correspondence Address: SAWYER LAW GROUP LLP, P.O. Box 51418, Palo Alto, CA, 94303, US

(21) Appl. No.: 10/931,179

(22) Filed: Aug. 31, 2004

(51) Int. Cl. H03K 19/0175

(52) U.S. Cl. 326/62

(57) ABSTRACT

A low leakage current power regulator is disclosed. The low leakage current power regulator comprises a starter, a leakage holder, a discharger and a linear regulator. The regulator provides a low current to the chip when a low current consumption part is active and provides a high current to the chip when a high current consumption logic is active. The power regulating technique in accordance with the present invention serves to reduce the standby current to a negligible level, keep the device alert to external instructions and provide a large enough working current (amps level).

### FIELD OF THE INVENTION

The present invention relates generally to low power technology and more particularly to provide ultra low leakage current in IC design.

### BACKGROUND OF THE INVENTION

In portable applications, battery life is very critical. The devices remain in standby mode most of the time. For example, cellular phone is often used for a few minutes each day, but the battery should be on for 24 hours. Hence standby leakage becomes a very important design specification.

FIG. 1 shows a conventional chip 10. A conventional power source 12 provides current to the regulator 14. The chip 10 is divided into two parts. One is the interface part (interface control logic) 16 which handles the instruction provided from the host. The other part of the chip 10 is a high-speed data processing part (digital logic core) 18. Current low power technology (for example, widely used 0.18 um CMOS technology) suffers high leakage current. It is hard to keep the whole device leakage at low level due to low MOSFET threshold voltage. Particularly, when the chip temperature increases, the leakage current increases exponentially.

It is necessary to power a low voltage device with a higher power supply in some applications, such as in some cellular phones. 3V is used to power 1.8v device. The state-of-the-art implementation is to obtain 1.8v from 3v through a linear regulator. Because the device should respond to external instruction at any time, the regulator cannot be shut down. The regulator working current plus the device leakage make a much higher device standby current.

Accordingly, what is needed is a system and method for overcoming the above-identified problem. The present invention addresses such a need.

### SUMMARY OF THE INVENTION

A low leakage on-chip regulator is disclosed. The low leakage power regulator comprises a starter, a leakage holder, a linear regulator, and a discharger. The regulator provides a low current to both the interface logic and the digital core logic when the interface logic is active and provides a high current to both the interface logic and the digital core logic when the digital core logic is active.

The power regulating technique in accordance with the present invention serves to reduce the standby current to a negligible level, keep the device alert to external host instructions and provide a large enough working current (amps level).

### BRIEF DESCRIPTION OF THE DRAWINGS

FIG. 1 shows a conventional chip with on-chip regulator.

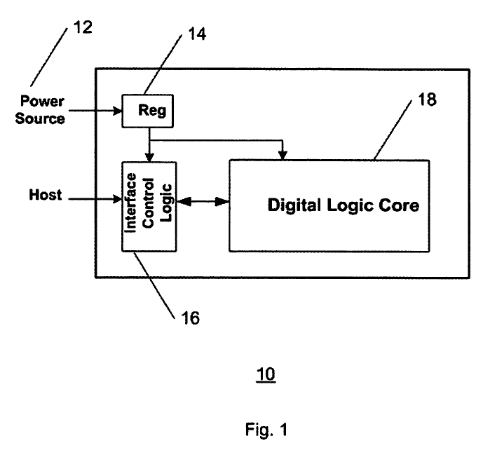

FIG. 2 shows a chip level block diagram in accordance with the present invention.

FIG. 3 shows a simplified structure of the low leakage current power regulator in accordance with the present invention.

FIG. 4 shows the timing diagram of the low leakage current in accordance with the present invention.

### DETAILED DESCRIPTION

The present invention relates generally to low power technology and more particularly to provide low leakage in IC designs. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

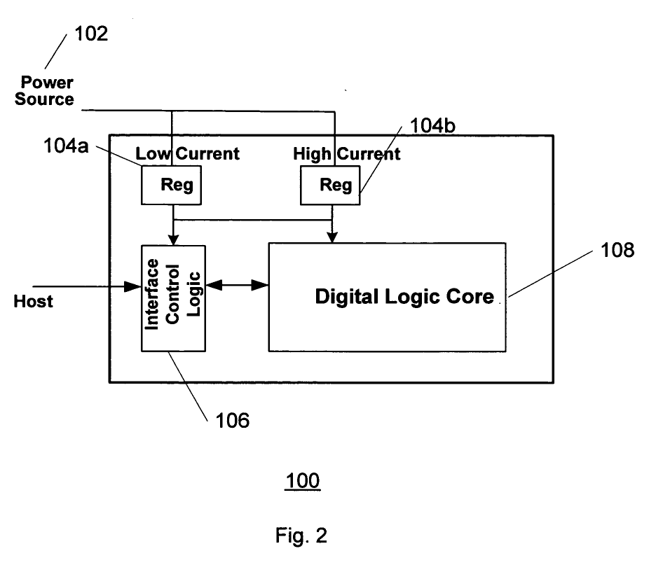

FIG. 2 shows a chip level block diagram of the low leakage power regulator in accordance with the present invention. The chip 100 is divided into two parts. Regulators 104a and 104b provide a regulated low current and a regulated high current. One part of the chip 100 is the interface part (interface logic) 106 which handles the external low speed instruction. The other part of the chip 100 is a high-speed data processing part digital logic core 108. The high-speed digital logic core 108 of the chip 100 is much larger than the interface control logic part 106.

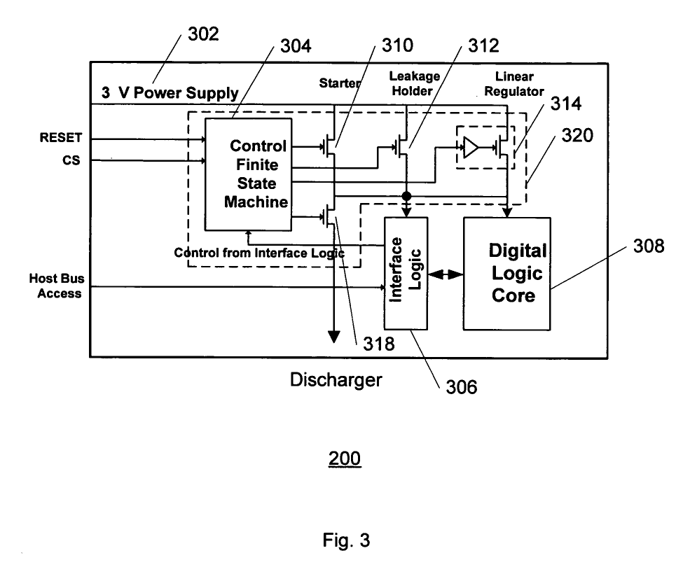

FIG. 3 shows a simplified structure of the low leakage power regulator in accordance with the present invention. A 3 volt power supply provides current to the chip 200. The chip 200 comprises a low leakage current regulator 320, an interface logic 306 and a digital core logic 308, where the control finite state machine 304, the starter 310, the leakage holder 312, the discharger 318 and the linear regulator 314 form the low leakage current regulator 320. The regulator 320 has three working states based on the power consumption, as shown in the below-identified Table 2.1.

TABLE 2.1

| State | |
|---|---|
| Name | Description |
| Idle | Interface control logic and data processing parts are all off. |
| Standby | Interface control logic is on, but the data processing part is off. |
| Normal | Both the interface control logic and the data processing are on. |

In order to describe these states and the operation of the invention in more detail refer now to the following discussion. The starter 310 is used to accelerate the leakage holder power-on speed as well as initialize the chip 200 so that the chip 200 can have the correct initial output state even when internal power is off.

The leakage holder 312 is used to provide low driving ability power for the chip 200 (less than 2 milliamp). When the leakage holder 312 is ready, the starter 310 is turned off. Because the circuit can be powered on promptly due to the starter 310, the interface control logic part 306 can respond to the external instructions on time.

The high driving ability linear regulator 314 is used to provide high driving ability for the chip 200 (greater than 100 milliamp). The linear regulator 314 is turned on just before the digital logic core 308 begins to work. The discharger 318 is used to discharge the Vdd line in idle mode.

When reset is effective, the starter 310 is turned on. The interface control logic 306 and the digital logic core 308 are all reset correctly. All outputs have their correct initial values.

After reset, the device is in idle mode, the starter 310, the leakage holder 312 and the linear regulator 314 are all off; the discharger 318 is on; hence the only leakage current is the control finite state machine 304, which includes less than 100 high-threshold gates. The idle current is hence very low, less than 1% of the whole device idle current.

When the chip 200 is selected by CS signal, the starter 310 is turned on temporarily, the leakage holder 312 is turned on, the discharger 318 is off. Hence the chip 200 is turned on very fast and the voltage is stable for the interface control logic 306.

After the leakage holder 312 is turned on, the host can operate the chip 200 by the host interface control logic 306. The host can then turn on/off the high driving ability part by setting certain registers in the interface control logic part 306. The host can also turn off the leakage holder 304 by writing certain registers in the interface control logic part 306 or just simply reset the chip 200.

A system and method in accordance with the present invention can be utilized in a variety of applications. For example, the digital core logic could implement a cell phone, PDA, MP 3 player, CD player or other portable device in which the device may remain on standby most of the time, but the battery should be on.

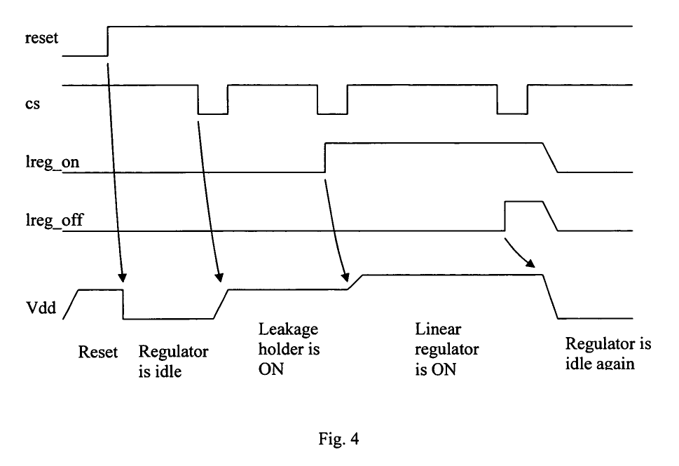

FIG. 4 shows the timing diagram of the low leakage regulator in accordance with the present invention. Where CS and reset are low effective signals from host. Lreg_on and Lreg_off are from internal registers in the interface control logic 306. The host sets their values.

Although the present invention has been described in accordance with the embodiments shown, one of ordinary skill in the art will readily recognize that there could be variations to the embodiments and those variations would be within the spirit and scope of the present invention. Though a system and method in accordance with the present invention is implemented for a slave chip, it can be used as a standalone chip with minor regulator control logic change, such as adding some control logic in the regulator control finite state machine 304 so that the chip can change its state as it needs to. Accordingly, many modifications may be made by one of ordinary skill in the art without departing from the spirit and scope of the appended claims.

What is claimed is:

1. An integrated circuit chip comprising:
a low current consumption part;
a high current consumption part; and
an on-chip regulator, wherein the regulator provides a low current to the chip when the low current consumption part is active and provides a high current to the chip when the high current consumption part is active.

2. The integrated circuit chip of claim 1 wherein the on-chip regulator comprises:
a leakage holder for providing a low current to the chip;
a starter, for initializing the chip; and accelerating the leakage holder;
a linear regulator for providing a high current to the chip; and
a discharger for discharging the chip; and
a state machine for controlling the starter, leakage holder, discharger and linear regulator.

3. The integrated chip of claim 2 wherein the state machine provides three working states, an idle state wherein the low and high current consumption part are off, a standby state wherein the low current consumption part is on and the high current consumption part is off and a normal state, wherein both the low and high current parts are on.

4. The integrated circuit chip of claim 1 wherein the low current consumption part comprises an interface logic.

5. The integrated circuit chip of claim 1 wherein the high current consumption part comprises a digital core logic.

6. The integrated circuit chip of claim 5 wherein the digital core logic could implement any digital logic.

7. An on-chip regulator for an integrated circuit chip, the regulator comprising:
a leakage holder for providing a low current to the chip;
a starter, for initializing the chip; and accelerating the leakage holder;
a linear regulator for providing a high current to the chip; and
a discharger for discharging the chip; and
a state machine for controlling the starter, leakage holder, discharger and linear regulator.

8. The integrated chip of claim 7 wherein the state machine provides three working states, an idle state wherein the low and high current consumption part are off, a standby state wherein the low current consumption part is on and the high current consumption part is off and a normal state, wherein both the low and high current parts are on.
